(19) United States
(12) Patent Application Publication
(10) Pub. No.: US 2008/0265911 A1
(43) Pub. Date: Oct. 30, 2008

(54) Power Sensing Module with Built-In Mismatch and Correction

(75) Inventor: Eric Breakenridge, Clackmannshire (GB)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 12/172,274

(22) Filed: Jul. 14, 2008

(51) Int. Cl. G01R 31/34

(52) U.S. Cl. 324/638; 702/60

(57) ABSTRACT

A module determines the mismatch corrected power output of a generator. Loads within the module provide at least three different load values. At least one power sensor detects at least a portion of the power output by the generator for each of the load values. Input electrical paths transmit power from the generator to the loads. At least one output electrical path transmits signals from the at least one power sensor indicative of power received when the generator is electrically connected to the different load values.

### BACKGROUND OF THE INVENTION

FIG. 1 shows a power measurement setup 100 for measuring the power output from a generator 107 which is delivered to a load 103 having an impedance Z_{L}. The generator 107 has an internal impedance Z_{G} 105 and includes a source 101. The load 103 is part of a power sensor, which can be can be a heat-based (also called “thermal-based”) power sensor (also referred to as a thermal-based power sensor) or a diode-based power sensor (more generally a “rectification-based” power sensor). The generator 107 and load 103 can be connected using coaxial cable.

An example of a heat-based power sensor is the AGILENT 8481A thermocouple-based sensor. AGILENT is a trademark of Agilent Technologies, Inc. of Santa Clara, Calif., USA. Thermal-based power sensors are true “averaging detectors” and in addition to thermocouple power sensors also include bolometer (thermistor or barretter) power sensors. They convert an unknown RF power to heat and detect that heat transfer. In other words they measure heat generated by the RF energy.

Rectification-based power sensors include diode sensors such as low-barrier Schottky diodes and PDB diodes. The electric field of the input RF signal generates an AC voltage across the diode and this AC voltage is rectified by the diode into a DC voltage. This DC voltage is related to the power of the input RF signal.

Usually the power sensor sends signals indicative of the power received by it's load to a power meter, which can be an AGILENT E4418B Power Meter.

The most important source of error in power measurements of RF and microwave signals is the mismatch of generator and sensor. Even a signal generator with low SWR of 2, for example, can still lead to an additional uncertainty of the measurement result of ±3.5% (0.15 dB) or more. Although this error can be decisive for total measurement uncertainty, it has frequently not been taken into account because it could not be specified for the sensor alone.

Due to reflections caused by the mismatch of the generator and sensor, it is not the nominal power P_{GZ0} of the generator 107 that is transmitted to the load 103, but rather, the power P_{D} delivered to the load 103.

The actual value of the power P_{D} delivered from the generator 107 to the load 103 is derived in the following.

The reflection coefficient of the load 103 is related to the incident wave and the reflected wave at the load port thus:

$${Γ}_{L} = \frac{{b}_{L}}{{a}_{L}}$$

is the reflection coefficient at the load 103 where
   |a_{L}|²=P_{I} is the power incident to the load and
   |b_{L}|²=P_{R} is the power reflected from the load.

Now, at the generator, b_{G}=b_{S}+Γ_{G}·a_{G}, where:
b_{G} is the wave emerging from the generator 107,
a_{G} is the wave incident on the generator 107,
Γ_{G} is the reflection coefficient looking into the generator 107, and
b_{S} is the wave internal to the generator 107.

When the generator 107 is connected to the load 103 b_{G}=a_{L} and b_{L}=a_{G}.

This results in:

$${a}_{L} = \frac{{b}_{S}}{1 - {Γ}_{L} \cdot {Γ}_{G}} and$$

$${b}_{L} = \frac{{b}_{S} \cdot {Γ}_{L}}{1 - {Γ}_{L} \cdot {Γ}_{G}} .$$

So the net power dissipated at the load, P_{D}, and where P_{GL} is the net power delivered to the arbitrary load, is

$${P}_{D} = {P}_{GL} = {P}_{I} - {P}_{R} = {\vert {b}_{S} \vert}^{2} \cdot \frac{1 - {\vert {Γ}_{L} \vert}^{2}}{{\vert 1 - {Γ}_{L} \cdot {Γ}_{G} \vert}^{2}} .$$

The nominal power P_{SZ0} of the generator 107 that would be transmitted to the load 103 if there were no reflections would be:

P_{GZ0}=|b_{S}|².

If the load 103 is a conjugate match for the source 101 (condition for maximum power transfer) then P_{AV}, which is the maximum available power delivered into a conjugate matched load, is:

$${P}_{AV} = {\vert {b}_{S} \vert}^{2} \cdot \frac{1}{1 - {\vert {Γ}_{G} \vert}^{2}} .$$

So the ratio of the delivered power P_{D} to the available power P_{AV} (sometimes called the conjugate mismatch) is:

$$\frac{{P}_{GL}}{{P}_{AV}} = \frac{( 1 - {\vert {Γ}_{G} \vert}^{2} ) \cdot ( 1 - {\vert {Γ}_{L} \vert}^{2} )}{{\vert 1 - {Γ}_{L} \cdot {Γ}_{G} \vert}^{2}} .$$

If all the complex reflection coefficients are measured at the frequency of interest then their values can be fed into the equations above to calculate the available power P_{AV}. The determination of the available power P_{AV} is known as the mismatch corrected power measurement. Unfortunately the above equation is not often used for this mismatch corrected power measurement. Due to the difficulty in obtaining the complex reflection coefficients Γ_{G} of the generator 107 the mismatch uncertainty is lived with as a fact of life.

However, during the factory calibration of sensors, complex mismatch correction is performed. This can be done because the source is a vector network analyzer, with the capability to not only provide a signal but also to measure the complex S-parameters at the port. Thus, in the above equation Γ_{L} is known from factory calibration and Γ_{G} is the unknown.

Determining Γ_{G} in the above equation is not easy. Measurement of the source S-parameters or reflection coefficients is difficult when it is a live source. Reflection coefficients of 2-port linear networks are readily measured using vector network analyzers. The measurement of a live output is less readily achieved however as the network analyzer cannot introduce a signal at the generator's output frequency. Most methods make use of scalar techniques to derive the magnitude of the generator's reflection coefficients. In practice the maximum magnitude of the reflection coefficient will be all that is known.

It would be desirable to provide a compact, low loss and inexpensive module having built-in mismatch measurement and correction for measuring the power output by a generator.

### SUMMARY OF THE INVENTION

The present invention provides a compact, low loss and inexpensive module having built-in mismatch measurement and correction for measuring the mismatch corrected power output of a generator.

The module determines the mismatch corrected power output of a generator. Loads within the module provide at least three different load values. At least one power sensor detects at least a portion of the power output by the generator for each of the load values. Input electrical paths transmit power from the generator to the loads. At least one output electrical path transmits signals from the at least one power sensor indicative of power received when the generator is electrically connected to the different load values.

### BRIEF DESCRIPTION OF THE DRAWINGS

Further preferred features of the invention will now be described for the sake of example only with reference to the following figures, in which:

FIG. 1 shows a prior-art power measurement setup for measuring the power output from a generator which is delivered to a load

FIG. 2 shows a module of the present invention for measuring the mismatch corrected power output by a generator.

FIG. 3 shows a “reflectometer” embodiment of the module for measuring the mismatch corrected power output by a generator of the present invention.

FIG. 4 shows a “power splitter” embodiment of the present invention for measuring the mismatch corrected power output by a generator.

FIG. 5 shows an embodiment of the present invention making use of a “superposition” principal using a three-way power splitter to measure the mismatch corrected power output by a generator.

### DETAILED DESCRIPTION

The present invention allows automatic measurement of generator S-parameters or complex reflection coefficients. The measurement process combines this measurement with a basic power measurement and load complex reflex coefficients (or load S-parameters) to produce a mismatch corrected power measurement.

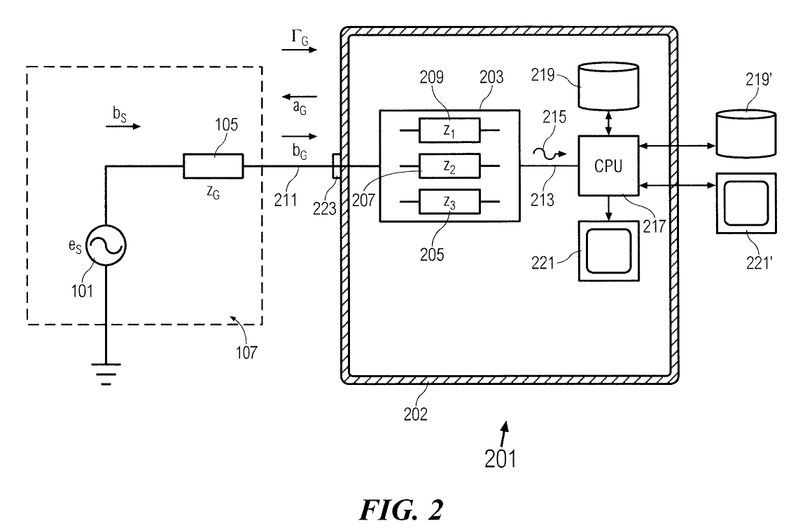

FIG. 2 shows an embodiment of a module 201 for measuring the mismatch corrected power output by the generator 107 of the present invention. The module 201 can be enclosed within a housing 202.

It is known in the art that presenting (or electrically connecting) various loads to the generator 107 can be used to determine the match of the generator. The match of the generator is based on any of the related parameters: complex voltage reflection coefficients (VRC), S-parameters or complex impedance.

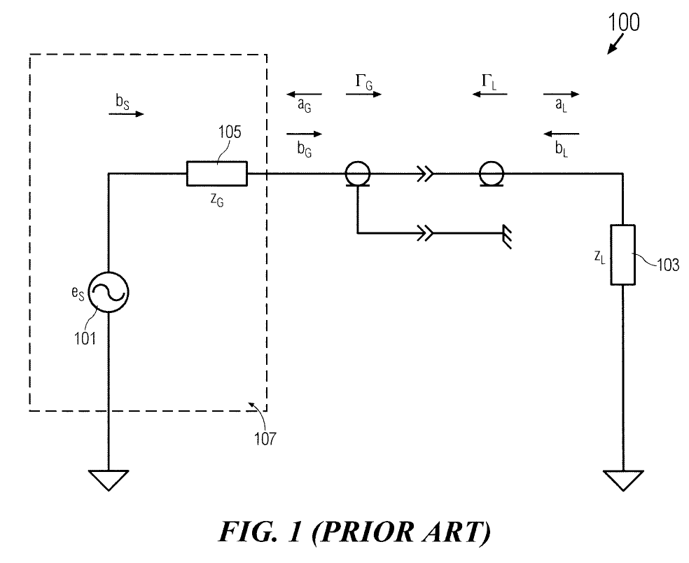

The generator 107 can be the same as that described with reference to FIG. 1 above, including the impedance Z_{G} 105 and the source 101.

Again, as in FIG. 1, b_{G} is the wave emerging from the generator 107, a_{G} is the wave incident on the generator 107, and b_{S} is the wave internal to the generator 107.

The waves b_{S}, b_{G} and a_{G} can have a frequencies in the RF range. The RF frequency range is considered to cover frequencies from approximately 150 kHz up to the IR range. In other embodiments the frequency can be in the microwave frequency range of 1 GHz and higher.

The module 201 includes a load section 203. Loads 205, 207, 209 are shown within the load section 203. In general the load section 203 should have loads with at least three different load values. Rather than three separate loads, one or two loads having variable load values can be used instead. Three or more loads with or without variable load values can also be used in the invention. At least one of the loads 205, 207, 209 is included in a power sensor (not shown). The loads 205, 207, 209 can be fixed resistors, variable resistors or distributed impedances, for example.

A single power sensor can also be used to measure the power across more than one of the loads. In such an embodiment the number of power sensors can be less than the number of loads. Also, a single power sensor can be used with a single variable load.

Input electrical paths 211 transmit power from the source 101 and generator 107 to the module 201 and loads 205, 207, 209 within the load section 203. The input electrical paths 211 and other transmission media used in the invention can be cable, waveguide, transmission line or other known transmission media. The various components of the module can be mounted on a PC board or other substrate. The housing 202 of the module 201 can include an input connector 223 for receiving the waves b_{S}, b_{G} and a_{G}.

Output electrical paths 213 transmit signals 215 from one or more power sensors indicative of the amount of power received when the generator is electrically connected to any of the load values. The signals 215 can be analogue or digital. The module 201, or the load section 203 within the module 201, can include power sensors and/or power meters having analogue or digital signals to output the signals 215. Alternatively, the load section 203 or module 201 can include one or more analogue to digital (A/D) converters to output digital signals such as a digital signal 215.

A processor 217 receives the information transmitted by the signals 215 and from these signals calculates the complex voltage reflection coefficients (VRC), S-parameters or complex impedance of the generator 107. The signals 215 can also include a basic power measurement of the net power P_{GL} delivered by the generator 107 to the load of the sensor. The processor 217 also receives, for example from a storage media 219, previously stored load complex reflex coefficients Γ_{L} (or load S-parameters) of the sensor (the same or similar sensor used to measure the net power P_{GL}). The processor 217 combines this data to calculate a mismatch corrected power measurement.

Once the complex voltage reflection coefficients (VRC), S-parameters or complex impedance of the generator 107 are determined, the values can be combined with the measured net power P_{GL} delivered by the generator 107 to the load of the sensor, and the stored complex voltage reflection coefficients (VRC), S-parameters or complex impedance of the sensor, to yield a more accurate power measurement. This can be presented as source power and impedance, or s-parameter, to fully characterize the source.

The processor 217 uses the values for Γ_{G}, P_{GL} and Γ_{L} to calculate the mismatch corrected power output P_{AV} of the generator 107 using the equation:

$$\frac{{P}_{GL}}{{P}_{AV}} = \frac{( 1 - {\vert {Γ}_{G} \vert}^{2} ) \cdot ( 1 - {\vert {Γ}_{L} \vert}^{2} )}{{\vert 1 - {Γ}_{L} \cdot {Γ}_{G} \vert}^{2}} .$$

The processor 217 can store information on a storage media 219 and can display data or results on a display 221. The processor 217, storage media 219, and display 221 can each be integral to the housing 202 of the module 201, as illustrated. In another embodiment, any of the processor 217, storage media 219, and display 221 can be external to the housing 202 of the module 201. For example, in FIG. 2, this alternative embodiment is illustrated with a storage media 219′ and a display 221′ external to the housing 202.

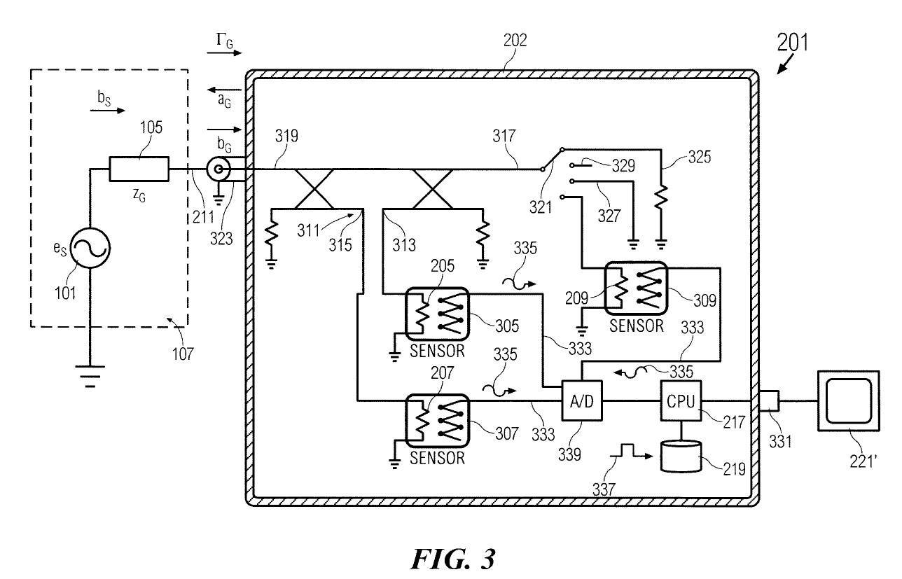

FIG. 3 shows a particular embodiment of the module 201 for measuring the mismatch corrected power output by the generator 107 of FIG. 2. This embodiment makes use of a coupler 311 to provide a “reflectometer” implementation.

Again, as in FIGS. 1 and 2, b_{G} is the wave emerging from the generator 107, a_{G} is the wave incident on the generator 107, and b_{G} is the wave internal to the generator 107.

The module 201 includes the coupler 311 for distributing power from the generator 107 to sensors 305, 307, 309. The coupler can be a transmission line directional coupler, for example. The coupler 311 includes coupled output ports 313, 315, an input port 319 and a through-port 317.

Input electrical paths 211 transmit power from the source 101 and generator 107 to the module 201 and loads 205, 207, 209 within the sensors 305, 307, 309. The housing 202 of the module 201 can include an input connector 323 for receiving the waves b_{S}, b_{G} and a_{G}. The input electrical paths 211 pass through the input connector 323 and the input port 319 into the coupler 311, and lead to the coupled output ports 313, 315, and the through-port 317.

Electrically connected to the through-port 317 is an electrical switch 321. The switch 321 presents, or electrically connects, a load 325, short 327, open 329 and sensor 309 connections to the generator 107.

The sensor 305 receives power output from the coupled output port 313 and the sensor 307 receives power output from the coupled output port 315, and the sensor 309 receives power output from the through-port 317 and passing through the electrical switch 321.

The three sensors 305, 307, 309 provide measurements that are combined to evaluate the quantities required.

The two sensors 305, 307 on the coupled output ports 313, 315, respectively, provide measurements of the incident and reflected wave under all the conditions of the switch 321 for determining Γ_{G}. As mentioned above, the switch 321 presents load, short, open and sensor connections. When the switch 321 is positioned to the load 325 position, it is preferable that a mismatch (e.g. 100 Ohm) is presented. Measurements under all the switch positions are used to ensure the source match can be found.

The load values of the load 325, short 327, and open 329, as well as the loads 205, 207, 209 can be considered to be within the load section 203 (see FIG. 2).

The switch 321 is positioned to the sensor 309 position for use in determining P_{GL}. Preferably the load 209 of the sensor 309 presents a matched “Z0” load (e.g. 50 Ohm). Under this condition the sensor 309 has the best sensitivity for measuring the power.

Output electrical paths 333 transmit signals 335 indicative of the amount of power received by the sensors 305, 307, 309. The signals 335 can be analogue or digital. Alternatively, the load section 203 or module 201 can include one or more analogue to digital (A/D) converters 339 to output digital signals such as a digital signal 337.

The processor 217 receives the information transmitted by the signals 335 or 337 and from these signals calculates the complex voltage reflection coefficients (VRC), S-parameters or complex impedance of the generator 107. The processor 217 calculates the mismatch corrected power output P_{AV} of the generator 107.

The processor 217 stores information on the storage media 219 and displays data or results on a display 221′.

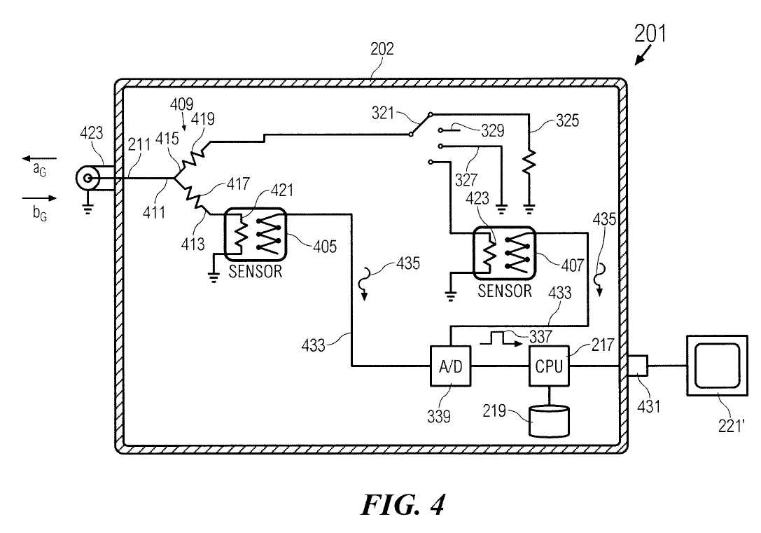

FIG. 4 shows another particular embodiment of the module 201 for measuring the mismatch corrected power output by the generator 107 of FIG. 2. This embodiment makes use of a power splitter 409 to provide a “power splitter” implementation. This power splitter embodiment is similar to the reflectometer embodiment described above with reference to FIG. 3, except that forward and reflected powers are not measured directly.

Again, as in FIGS. 1, 2 and 3, b_{G} is the wave emerging from the generator 107, a_{G} is the wave incident on the generator 107, and b_{S} is the wave internal to the generator 107.

The module 201 includes the power splitter 409 for distributing power from the generator 107 to sensors 405 and 407. The power splitter 409 can be a transmission line power splitter, for example. The power splitter 409 includes an input port 411, an output arm 413 having an impedance 417 and an output arm 415 having an impedance 419.

Input electrical paths 211 transmit power from the source 101 and generator 107 (see FIG. 2) to the module 201 and loads 421, 423 within the sensors 405, 407. The housing 202 of the module 201 can include an input connector 423 for receiving the waves b_{S}, b_{G} and a_{G}. The input electrical paths 211 pass through the input connector 423 to the input port 411 of the power splitter 409, and then to the output arms 413, 415.

Electrically connected to output arm 415, as in the embodiment of FIG. 3 is the electrical switch 321. The switch 321 presents the load 325, short 327, open 329 and sensor 407 connections to the generator 107.

The sensor 405 receives power output from the output arm 413 and the sensor 407 receives power output from the output arm 415 and passing through the electrical switch 321.

The two sensors 405, 407 provide measurements that are combined to evaluate the quantities required.

The sensor 405 on the output arm 413 provides measurements of the power under all the conditions of the switch 321 for determining Γ_{G}. As mentioned above, the switch 321 presents load, short, open and sensor connections. When the switch 321 is positioned to the load 325 position, it is preferable that a mismatch (e.g. 100 Ohm) is presented.

Measurements under all the switch positions are used to ensure the source match can be found.

The load values of the load 325, short 327, and open 329, as well as the loads 417, 419, 421, 423 can be considered to be within the load section 203 (see FIG. 2).

The switch 321 is positioned to the sensor 407 position for use in determining P_{GL}. Preferably the load 423 of the sensor 407 presents a matched “Z0” load (e.g. 50 Ohm). Under this condition the sensor 407 has the best sensitivity for measuring the power.

Output electrical paths 433 transmit signals 435 indicative of the amount of power received by the sensors 405, 407. The signals 435 can be analogue or digital. Alternatively, the load section 203 or module 201 can include one or more analogue to digital (A/D) converters 339 to output digital signals such as a digital signal 337.

The processor 217 stores information on the storage media 219 and displays data or results on a display 221′.

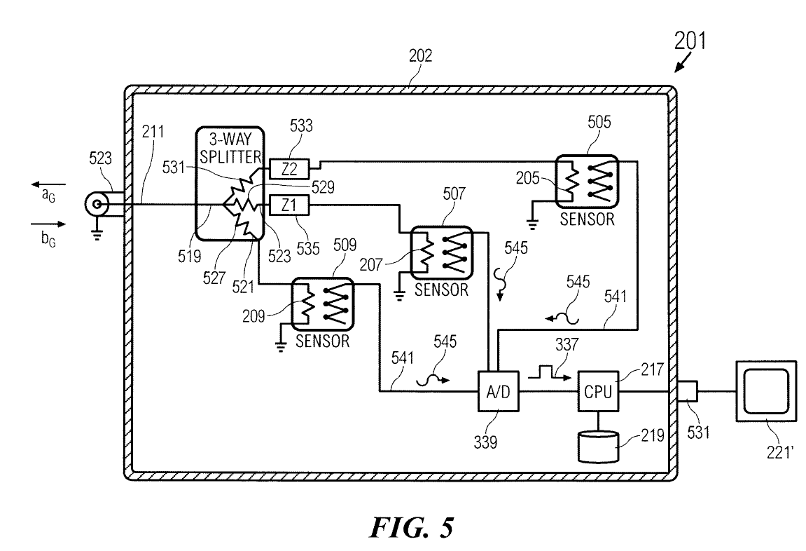

FIG. 5 shows another particular embodiment of the module 201 for measuring the mismatch corrected power output by the generator 107 of FIG. 2. This embodiment makes use of a three-way power splitter 511 to provide a “superposition” implementation. This superposition embodiment does not require the switch 321 of the embodiments of FIGS. 3 and 4.

Again, as in FIGS. 1-4, b_{G} is the wave emerging from the generator 107, a_{G} is the wave incident on the generator 107, and b_{G} is the wave internal to the generator 107.

The module 201 includes the three-way power splitter 511 for distributing power from the generator 107 to sensors 505, 507, 509. The power splitter 511 can be a transmission line power splitter, for example. The power splitter 511 includes an input port 519, a first output arm 521 having an impedance 527, a second output arm 523 having an impedance 529, and a third output arm 525 having an impedance 531.

Input electrical paths 211 transmit power from the source 101 and generator 107 (see FIG. 2) to the module 201 and loads 205, 207, 209 within the sensors 505, 507, 509. The housing 202 of the module 201 can include an input connector 523 for receiving the waves b_{S}, b_{G} and a_{G}. The input electrical paths 211 pass through the input connector 523 to the input port 519 of the power splitter 511, and then to the output arms 521, 523, 525.

The sensor 505 receives power output from the output arm 525 through the impedance Z2 533, the sensor 507 receives power output from the output arm 523 through the impedance Z1 535, and the sensor 509 receives power output from the output arm 521.

Three different power measurements of the net power delivered by the generator 107 are made by the sensors 505, 507, 509.

The load values of the impedances Z1 535 and Z2 533, as well as of the loads 205, 207, 209 can be considered to be within the load section 203 (see FIG. 2).

The sensor 509 is used in determining P_{GL}. Preferably the load 209 of the sensor 509 presents a matched “Z0” load (e.g. 50 Ohm). Under this condition the sensor 509 has the best sensitivity for measuring the power.

Output electrical paths 541 transmit signals 545 indicative of the amount of power received by the sensors 505, 507, 509. The signals 545 can be analogue or digital. Alternatively, the load section 203 or module 201 can include one or more analogue to digital (A/D) converters 339 to output digital signals such as a digital signal 337.

The processor 217 stores information on the storage media 219 and displays data or results on a display 221′.

In the foregoing specification, the invention has been described with reference to specific exemplary embodiments thereof. The specification and drawings are, accordingly, to be regarded in an illustrative sense rather than a restrictive sense.

1. A module for determining the mismatch corrected power output of a generator comprising:
loads within the module providing at least three different load values;
at least one power sensor for detecting at least a portion of the power output by the generator for each of the at least three different load values;
input electrical paths for transmitting power from the generator to the loads; and
at least one output electrical path for transmitting signals from the at least one power sensor indicative of power received when the generator is electrically connected to the at least three different load values.

2. The module of claim 1, wherein each of the loads has a different load value.

3. The module of claim 1, further comprising an additional power sensor for measuring net power delivered from the generator.

4. The module of claim 1, further comprising:
a processor for receiving information provided by the signals from the at least one power sensor and using the information to calculate the mismatch corrected power output of the generator using calculated complex voltage reflection coefficients of the generator.

5. The module of claim 1, further comprising a housing enclosing the module.

6. The module of claim 4, further comprising coaxial connectors attached to the housing and electrically connected to the input electrical paths for transmitting the power to the loads.

7. The module of claim 1, further comprising:
a directional coupler through which the input electrical paths pass;
a first coupling port for transmitting a forward directed wave to a first of the loads;
a second coupling port for transmitting a reverse directed wave to a second of the loads; and
a through port for electrically connecting the at least three different load values to the generator.

8. The module of claim 7, further comprising a switch electrically connected to the through port for switching between the loads within the module and electrically connecting at least three different load values to the generator.

9. The module of claim 1, further comprising sensors for measuring power transmitted to the first and second of the loads for each of the at least three different load values electrically connected to the generator.

10. The module of claim 1, further comprising:
a power splitter through which the input electrical paths pass;
a first arm of the power splitter for transmitting a wave to a first of the loads; and
a second arm of the power splitter for electrically connecting the at least three different load values to the generator;

11. The module of claim 10, further comprising a switch electrically connected to the second arm for switching between the loads within the module and electrically connecting at least three different load values to the generator.

12. The module of claim 10, further comprising a sensor for measuring power transmitted to the first of the loads for each of the at least three different load values electrically connected to the generator.

13. The module of claim 1, further comprising:
a power splitter through which the input electrical paths pass;
a first arm of the power splitter for transmitting a wave to a first of the loads;
a first power sensor for measuring power passing through the first of the loads;
a second arm of the power splitter for transmitting a wave to a second of the loads;
a second power sensor for measuring power passing through the second of the loads; and
a third arm of the power splitter for transmitting a wave directly to a third power sensor for measuring power passing through the third arm of the power splitter.

14. A method for determining the mismatch corrected power output by a generator comprising the steps of:
measuring the power delivered by the generator when electrically connected to a first load value;
measuring the power delivered by the generator when electrically connected to a second load value;
measuring the power delivered by the generator when electrically connected to a third load value;
measuring the power delivered by the generator to a load;
calculating complex reflection coefficients of the generator from the measured power delivered by the generator;
calculating the mismatch corrected power output of the generator using the calculated complex reflection coefficients of the generator, complex reflection coefficients of the load and power delivered by the generator to the load; and
outputting an indication of the mismatch corrected power output of the generator.
